(19) United States
(12) Patent Application Publication
(10) Pub. No.: US 2025/0236977 A1
(43) Pub. Date: Jul. 24, 2025

(54) Group III/IV/V-assisted heteroepitaxial growth of II-(IV/V)-N optoelectronic semiconductors

(71) Applicant: Alliance for Sustainable Energy, LLC, Golden, CO (US)

(72) Inventors: John Stanley MANGUM, Englewood, CO (US); Andriy ZAKUTAYEV, Boulder, CO (US); Ann London GREENAWAY, Lakewood, CO (US)

(21) Appl. No.: 19/032,753

(22) Filed: Jan. 21, 2025

Related U.S. Application Data
(60) Provisional application No. 63/622,826, filed on Jan. 19, 2024.

(51) Int. Cl. C25B 11/087; C25B 11/052; C25B 11/067; C30B 23/02; C30B 29/38

(52) U.S. Cl. CPC C25B 11/087; C25B 11/052; C25B 11/067; C30B 23/025; C30B 29/38

(57) ABSTRACT

Described herein are devices and methods for the heteroepitaxial growth of II-(I/V)-N optoelectronic semiconductors using enhanced growth parameters and isovalent substitution to include a group III, IV or V additive at some cation sites. The described growth conditions and additive lead to increased optoelectronic properties (e.g., resistivity, carrier mobility, carrier concentration and bandgap) as well as improved surface morphology (e.g., surface roughness, crystal structure).

### CROSS-REFERENCE TO RELATED APPLICATIONS

This application claims priority from U.S. Provisional Patent Application No. 63/662,826, filed on Jan. 19, 2024, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### SUMMARY

Described herein are devices and methods for the heteroepitaxial growth of II-(IV/V)-N optoelectronic semiconductors using enhanced growth parameters and isovalent substitution to include a group III, IV or V additive on some cation sites. The described growth conditions and additive lead to increased optoelectronic properties (e.g., resistivity, carrier mobility, carrier concentration and bandgap) as well as improved surface morphology (e.g., surface roughness, crystal structure).

As an example, the present application demonstrates heteroepitaxial growth of high-quality sputtered ZnTiN₂ thin films using Sn to assist the growth and thereby improve optoelectronic properties and significantly reduce surface roughness. Without supplying Sn during growth, ZnTiN₂ films with good crystalline quality can be produced but their optoelectronic are poor with undesirably high carrier concentrations, likely due to extrinsic defects. However, when the ZnTiN₂ films are grown with the addition of Sn, films exhibit a significant enhancement of optoelectronic properties and reduced surface roughness compared to films grown under any conditions without the incorporation of Sn.

Prior work has demonstrated the synthesis of wurtzite-structure ZnTiN₂ and indicated that the optoelectronic properties and chemical stability mechanisms of this novel nitride semiconductor would be highly suitable for photoelectrochemical carbon dioxide reduction applications (PEC CO₂R). However, the initial ZnTiN₂ films exhibited poor optoelectronic quality that would hinder PEC device performance. The present application describes improvements to those properties using high temperature growth and templating substrates. Furthermore, additive (additional group III/IV/V elements, such as Sn) incorporation can used to improve the ZnTiN₂ thin film crystalline quality and optoelectronic properties beyond those two general improvements to the growth process. This technology leads to ZnTiN₂ with more efficient photon absorption and longer carrier lifetimes, which is important for multiple applications. This is also a demonstration of the use of group III/IV/V-assisted radiofrequency sputtering to improve optoelectronic properties. The invention described here should also be beneficial for improving material quality and optoelectronic properties in other ternary nitride systems, such as ZnGeN₂, Zn₂NbN₃, and Mg₂NbN₃.

In an aspect, provided is a device comprising: a) a first cation selected from group II, a second cation selected from group IV or group V and a nitride anion; b) an additive selected from group III, group IV or group V; c) wherein the additive replaces a portion of the first cation and/or the second cation via isovalent substitution thereby improving surface morphology, optoelectronic properties, or both; and d) wherein the device is an optoelectronic semiconductor.

In an aspect, provided is a method comprising: a) growing a semiconductor comprising a first cation selected from group II, a second cation selected from group IV or group V and a nitride anion on a sapphire substrate at a temperature greater than or equal to 100° C.; and b) substituting the first cation, the second cation or both with an additive selected from group III, group IV or group V.

The improved surface morphology and optoelectronic properties may be a result of the additive substation of the cation or the growth conditions (i.e., the substrate and temperature) or a combination thereof. Examples of improved surface morphology include surface roughness and improvements to crystal structure. Examples of optoelectronic properties include lower resistivity, changes in bandgap, changes in carrier concentration and the like.

The additive may be selected from Sn, Sb or Bi. In an embodiment, the additive may be Sn. The additive may replace a portion of the first cation, the second cation or both.

The device may be grown on a sapphire substrate, for example, a sapphire substrate with a c-plane (001) orientation.

The device may be grown at an elevated temperature, for example, a temperature greater than or equal to 50° C., 100° C., 150° C., 200° C., 250° C. or 300° C. In some embodiments, the growth temperature is about 275° C., 300° C. or 325° C.

As described herein, the device may have a reduced resistivity in comparison to a device without the additive, the sapphire substrate, the elevated temperature or a combination thereof. The device may have a resistivity less than or equal to 3.0 Ω-cm, 2.0 Ω-cm, 1.5 Ω-cm, or optionally, 1.0 Ω-cm.

The device may have a reduced bandgap in comparison to a device without the additive, the sapphire substrate, the elevated temperature or a combination thereof. For example, the device may have a bandgap selected from the range of 1 to 3 eV, 1.5 to 2.5 eV, 1.75 to 2.25 eV. In some embodiments, the device may have a bandgap of about 2.0 eV.

The device may also have an increased carrier mobility in comparison to a device without the additive, the sapphire substrate, the elevated temperature or a combination thereof. For example, the device may have a carrier mobility greater than or equal to 0.005 cm²V⁻¹s⁻¹, 0.01 cm²V⁻¹s⁻¹, 0.02 cm²V⁻¹s⁻¹, 0.03 cm²V⁻¹s⁻¹, or 0.04 cm²V⁻¹s⁻¹.

The device may have a reduced surface roughness in comparison to a device without the additive, the sapphire substrate, the elevated temperature or a combination thereof. For example, the device may have a surface roughness less than or equal to 2.0 nm, 1.5 nm or 1.0 nm, root mean squared.

The first cation may be selected from Zn and Mg. The second cation may be selected from Ti, Ge and Nb. In an embodiment, the first cation is Zn and the second cation is Ti.

The described method may include methods of semiconductor growth known in the art, including, for example, physical vapor deposition and/or sputtering.

### BRIEF DESCRIPTION OF DRAWINGS

Some embodiments are illustrated in referenced figures of the drawings. It is intended that the embodiments and figures disclosed herein are to be considered illustrative rather than limiting.

FIGS. 1A-1C provide two-dimensional (2θ and χ) X-ray diffraction of ZnTiN₂ films grown on different substrates and at various growth temperature setpoints (Tₛₚ): FIG. 1A ZnTiN₂ grown on Si at ambient temperature (ZnTiN₂-AT-Si); FIG. 1B ZnTiN₂ grown on sapphire at ambient temperature (ZnTiN₂-AT-sapph); and FIG. 1C ZnTiN₂ grown on sapphire at 300° C. (ZnTiN₂-300C-sapph). Integrated 1-dimensional plots are shown for each sample (below: Intensity vs. 2θ; right: Intensity vs. χ for the ZnTiN₂ (002) peak), with intensity normalized across the sample set. Film thickness, t_{film}, is reported for each. The ZnTiN₂-AT-sapph film shows greater (002) texturing compared to the ZnTiN₂-AT-Si film and the (002) orientation improves further when growth temperature is increased.

FIGS. 2A-2F provide plan-view (FIG. 2A) and cross-sectional (FIG. 2B) scanning electron microscopy from a ZnTiN₂-AT-Si film; plan-view (FIG. 2C) and cross-sectional (FIG. 2D) scanning electron microscopy micrographs from a ZnTiN₂-300C-sapph film; and plan-view (FIG. 2E) and cross-sectional (FIG. 2F) scanning electron microscopy micrographs from a Sn: ZnTiN₂-300C-sapph film. Ambient temperature growth on Si produces a polycrystalline (002)-textured columnar microstructure with a rough surface while growth on sapphire at elevated temperature results in a homogeneous and smooth ZnTiN₂ film.

FIG. 3A shows an EBSD inverse pole figure map from a ZnTiN₂ film grown on sapphire at 300° C. with Sn incorporated during growth (Sn: ZnTiN₂-300C-sapph) showing a homogeneous, (001)-oriented, single-crystal film. FIG. 3B provides the crystallographic directions of the color legend in (a) are shown schematically with respect to the wurtzite ZnTiN₂ crystal structure. FIG. 3C provides representative electron backscatter diffraction pattern from the Sn: ZnTiN₂ film that is indexed to a wurtzite crystal structure (P6₃mc space group). Three low-index Kikuchi bands are highlighted. FIG. 3D illustrates a {102} pole figure showing six-fold rotational symmetry, confirming single-crystal orientation in the planes off-axis from the growth direction.

FIG. 4A provides absorption coefficient vs. photon energy from spectroscopic ellipsometry for ZnTiN₂ films grown with varying growth conditions. Higher optical quality is indicated by a decrease in the degree of sub-gap (≲2 eV) absorption. Transient absorption kinetics of films grown with varying growth conditions at probe energies of (FIG. 4B) 1.8 eV and (FIG. 4C) 2.5 eV after photoexcitation at 3.1 eV. Normalized TA kinetic data are shown as markers and fits as solid lines.

FIGS. 5A-5D provide full transient absorption spectra corresponding to the films shown in FIGS. 4B and 4C.

FIGS. 6A-6B provide projected density of states of cation-ordered ZnTiN₂ supercells with 1.6% (FIG. 6A) Sn_{Ti} and (FIG. 6B) Sn_{Zn}. The inverse participation ratio is displayed on a color scale. The inset of (b) shows the charge density of the in-gap state, localizing on Sn_{Zn}.

FIGS. 7A-7B provide relative formation energy versus Sn substitution in two extreme chemical environments under different chemical potentials, within the ZnTiN₂ phase space, (FIG. 7A) Zn has the lowest chemical potential and Ti has the highest chemical potential (FIG. 7B) Zn has the highest chemical potential and Ti has the lowest chemical potential. The reference zero is chosen to be the lowest formation energy for all supercells we consider.

FIGS. 8A-8C provide projected density of states of cation-disordered ZnTiN₂ supercells (FIG. 8A) without Sn incorporation, (FIG. 8B) with all eight Sn substitutions on Ti sites (12.5% of cation sites), and (FIG. 8C) with Sn replacing one Zn site with the most Zn neighbors and seven randomly selected Ti sites. The inverse participation ratio for all supercells is displayed on a color scale. The three DOS graphs have different energy limits resulting from the addition of 2 e⁻ to the supercell in FIG. 8C, but the energy ranges are the same for comparison.

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

As used herein, the term “Group” refers to a set of elements which have an oxidation state of the described number. Group II elements have a +2 oxidation state, for example, Be, Zn, Cd, etc. Group III elements have a +3 oxidation state and so on.

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

### Example 1—Sn-Assisted Heteroepitaxy for the Improvement of ZnTiN₂ Photoabsorbers

Sustainable production of liquid fuels from abundant resources, such as carbon dioxide and water, may be possible through photoelectrochemical processes. Zinc titanium nitride (ZnTiN₂) is a potential photoelectrode semiconductor for photoelectrochemical fuel generation due to its ideal bandgap induced by cation disorder, shared crystal structure with established semiconductors, and self-passivating surface oxides under carbon dioxide reduction operating conditions. However, substantial improvements in crystalline quality and optoelectronic properties of ZnTiN₂ are needed to enable such applications. Described herein are improvements such as the heteroepitaxial growth of ZnTiN₂ on c-plane (001) sapphire substrates. Growth on sapphire improves crystal quality, while growth on sapphire at elevated temperatures (300° C.) yields highly oriented, single-crystal-like ZnTiN₂ films. When Sn is incorporated during these epitaxial growth conditions, notable improvements in ZnTiN₂ film surface roughness and optoelectronic properties are observed. The single-crystal-like, 12% Sn-containing ZnTiN₂ films exhibit a steep optical absorption onset at the band gap energy around 2 eV, electrical resistivity of 0.7 Ω-cm, and a carrier mobility of 0.046 cm²V⁻¹s⁻¹ with n-type carrier concentration of 2×10²⁰ cm⁻³. Density functional theory calculations reveal that moderate substitution of Sn (12.5% of the cation sites) on energetically preferred cation sites has negligible impact on the optoelectronic properties of cation-disordered ZnTiN₂. These results are important steps toward achieving high performance PEC devices based on ZnTiN₂ photoelectrodes with efficient photon absorption and photoexcited carrier extraction.

### Introduction

Photoelectrochemical carbon dioxide reduction (PEC CO₂R) may be a sustainable method of generating liquid fuels from abundant H₂O and CO₂, using sunlight as the energy input. Although there are many proposed structures for PEC devices, all are based around light-absorbing semiconductors as photoelectrodes, capturing photons and energizing charge carriers that are directed to perform reactions at the semiconductor-electrolyte interface. Such semiconductor photoelectrodes must withstand degradation while in direct contact with the harsh electrochemical environments necessary for PEC processes while maintaining high optoelectronic performance to maintain the flow of charge carriers to drive the PEC reactions. Although PEC CO₂R generally operates in less corrosive environments than PEC water splitting, the search for a stable and highly photocatalytically active semiconductor for CO₂R photoelectrodes is ongoing.

On one hand, PEC devices based on III-V semiconductors (e.g. GaInP) or Si offer exceptional optoelectronic properties as a result of those materials having highly optimized crystalline quality for photovoltaic applications, but readily degrade in PEC-relevant aqueous environments. There has been substantial progress in protecting III-V and Si photoelectrodes from corrosion using surface layers, such as TiO₂. However, these protective layers can parasitically absorb incident photons, thereby decreasing device efficiency, and certain passivation layers may not be sufficiently stable under conditions necessary for PEC CO₂R processes. On the other hand, emerging oxide semiconductors such as bismuth vanadate are attractive photoelectrode materials due to their long-term stability in harsh aqueous environments. However, these oxide-based material systems commonly lack structurally compatible substrates, which severely limits the production of high-quality films through heteroepitaxial growth methods. Even though these oxide photoelectrodes can remain stable for long durations, they ultimately suffer from inferior optoelectronic properties that limit charge carrier collection and therefore PEC device performance. There is a need for developing novel semiconductors that do not suffer from these inadequacies that impair the III-V and oxide material systems.

An ideal semiconductor for PEC CO₂R would couple long-term stability in aqueous electrochemical environments with the lessons from decades of high-quality semiconductor integration. With these criteria in mind, we recently used a co-design approach with high-throughput, combinatorial materials discovery to synthesize a new photoabsorber, ZnTiN₂, with potential for PEC CO₂R applications. ZnTiN₂ was predicted to have a crystal structure compatible with the established III-N semiconductor system and showed possibility of self-passivation under electrochemical conditions through the formation of stable surface oxides. The predicted bandgap of ZnTiN₂ (3.5 eV), which was calculated using density functional theory (DFT) with a hybrid functional and a cation-ordered unit cell, is too large for effective PEC applications. However, based from prior knowledge of ternary nitride systems, we expected experimentally synthesized ZnTiN₂ to exhibit cation-disordering that would sufficiently reduce the bandgap to an appropriate energy for PEC applications (˜2 eV). Previous work demonstrated the synthesis of wurtzite-structured (cation-disordered) ZnTiN₂ and indicated that the optoelectronic properties and chemical stability of this nitride semiconductor would be highly suitable for PEC CO₂R applications. Thin films of ZnTiN₂ were shown to remain stable under electrochemical polarization in CO₂R-relevant conditions following an initial transformation of the surface to a stable oxide layer.

However, the initial high-throughput ZnTiN₂ films exhibited a textured, polycrystalline microstructure due to growth on non-templating substrates (Si with native oxide and glass). Grain boundaries in polycrystalline films can be detrimental to device performance by increasing charge carrier scattering, as suggested by the low in-plane mobility of ZnTiN₂ (<0.1 cm²V⁻¹s⁻¹), and may also provide physical degradation pathways during PEC device operation. Continued work on ZnTiN₂ as a photoelectrode material therefore hinges on improvements to the crystalline quality of the material. It is prudent to borrow insights from established high-quality semiconductor synthesis processes to guide the optimization of ZnTiN₂ thin film growth, with the goal of developing growth conditions that can enhance the optoelectronic properties of ZnTiN₂ to fully realize this photoelectrode material in functional PEC devices.

There are three approaches that can be employed for improving material quality relative to preliminary ZnTiN₂ syntheses: (1) using single crystal substrates that are structurally compatible with the wurtzite ZnTiN₂ crystal structure to serve as templates for heteroepitaxial film growth, (2) enhancing adatom mobility at the growth surface by growing at elevated temperature, and (3) using isovalent surfactants, such as Sn in the case of ZnTiN₂, to promote two-dimensional layer-by-layer growth. In addition, high-throughput experimentation can be used to efficiently narrow down the wurtzite ZnTiN₂ deposition parameter space after initially implementing these approaches due to differences in Zn and Ti incorporation at elevated deposition temperature and on different substrates.

In this example, by employing these three strategies in concert, we demonstrate significant improvements in ZnTiN₂ crystalline quality and optoelectronic properties. X-ray diffraction and electron microscopy indicate heteroepitaxial alignment to c-plane (001) sapphire substrates and a homogenous single-crystal microstructure. Spectroscopic ellipsometry, transient absorption spectroscopy, and Hall effect measurements show a reduction in sub-bandgap optical absorption and longer photoexcited carrier lifetimes along with increased carrier mobility in the optimized Sn-containing ZnTiN₂ films. Furthermore, DFT calculations indicate that Sn substitution on energetically preferred cation sites in cation-disordered ZnTiN₂ has negligible effects on the electronic band structure and could alleviate local charge imbalance due to Zn clustering. The combination of these findings demonstrates critical steps in the optimization of ZnTiN₂ thin films for use in PEC applications.

### Results and Discussion

### Optimizing ZnTiN₂ Growth Parameters

Compositionally graded libraries of Zn₁₊ₓTi₁₋ₓN₂ thin films were initially deposited on Si, EXG glass, and c-plane (001) Al₂O₃ (sapphire) at ambient and elevated temperatures following the combinatorial growth procedures. Growth parameters were established for each set of growth conditions (i.e., substrate and growth temperature combination) that produced compositional gradients centered around stoichiometric ZnTiN₂ (equal amounts of Zn and Ti on the cation sublattice). Finally, homogeneous ZnTiN₂ films were deposited by rotating the substrate while growing using the refined growth parameters.

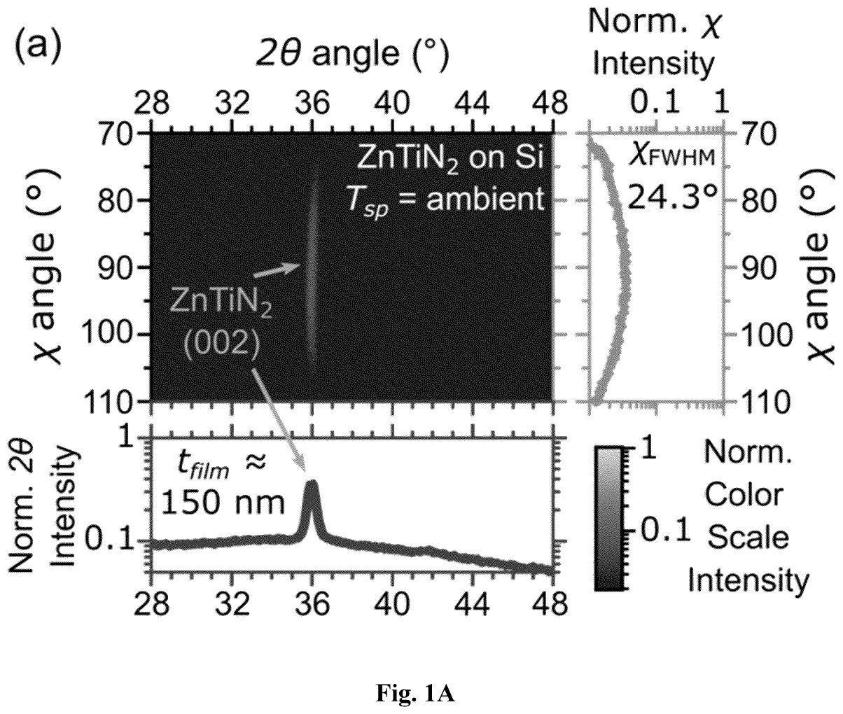

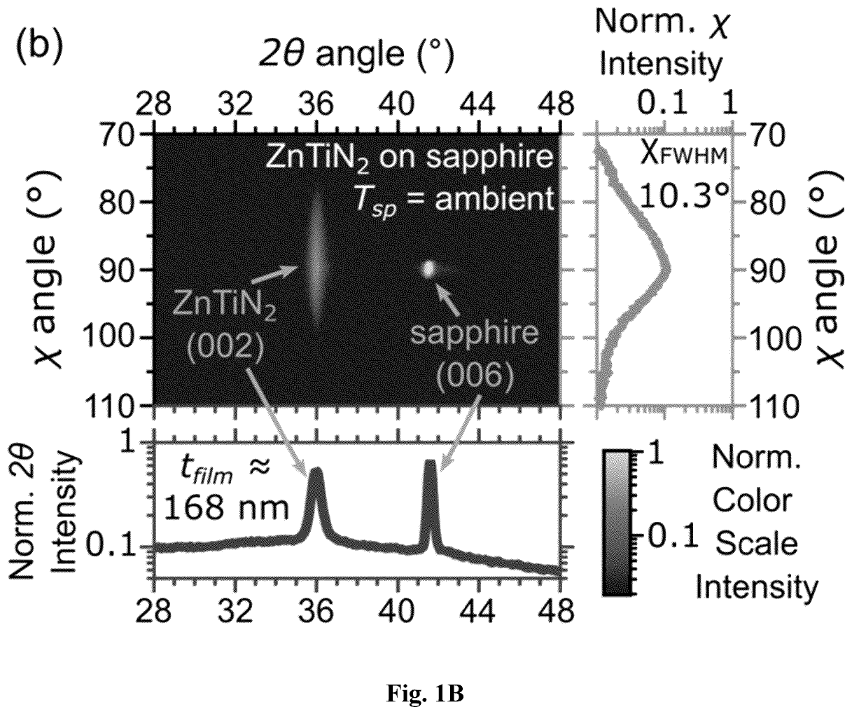

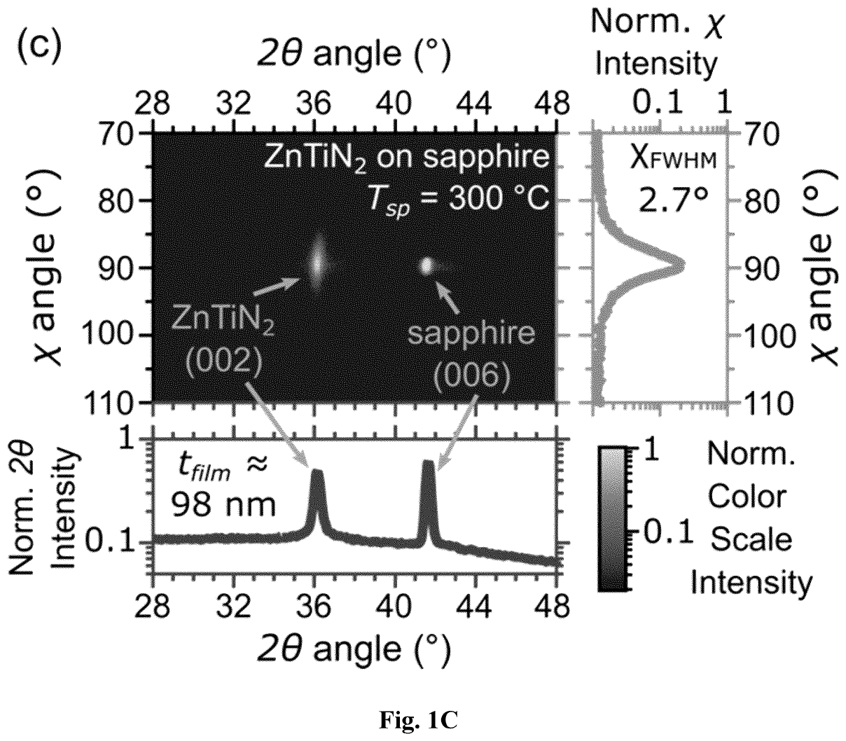

Nominally stoichiometric ZnTiN₂ films deposited on Si substrates with native oxide at ambient temperature (that is, with no intentional heating; hereafter referred to as “ZnTiN₂-AT-Si”) were investigated first and their crystallinity was measured by 2-dimensional X-ray diffraction (2D XRD) (FIG. 1A) to serve as a baseline. A single (002) diffraction peak from the wurtzite ZnTiN₂ crystal structure is observed, indicating that the film is textured with the (002) planes nominally parallel to the substrate surface. However, the (002) peak is broad in the χ direction, extending ±15° from the surface normal (χ=) 90°, indicating a relatively large degree of off-axis crystal tilting in the film microstructure, with full width at half max, χ_{FWHM}, of 24.3°. ZnTiN₂ films were then grown using the same conditions on c-plane (001) Al₂O₃ (hereafter referred to as “ZnTiN₂-AT-sapph”) which is commonly used as a structural template for growing films in the wurtzite crystal structure because of the shared hexagonal symmetry with sapphire. The same (002) crystallographic texture is observed in the ZnTiN₂-AT-sapph film (FIG. 1B), but the (002) peak profile exhibits a narrower χ range (±10° from the surface normal, χ_{FWHM}=10.3°) in comparison to the ZnTiN₂-AT-Si film.

Structural templating from the sapphire substrate provides a directed growth orientation that improves the alignment of the ZnTiN₂ (002) crystallographic film texture. However, sputtering is a physical vapor deposition method and not all incoming atoms may have the necessary energy and/or time to migrate to the ideal surface sites needed for building a highly oriented single crystal film. Increasing the substrate temperature can further improve film quality by enhancing the mobility of adatoms on the growth surface, leading to improved crystalline order in the growing film. This is clearly observed when increasing the growth temperature from ambient to a setpoint (Tₛₚ) of 300° C. for ZnTiN₂ deposition onto sapphire (hereafter referred to as “ZnTiN₂-300C-sapph”). Films grown under these more energetic conditions maintain the (002) texture seen in previous films and the (002) peak is significantly narrower in χ (±5° from the surface normal, χ_{FWHM}=) 2.7° (FIG. 1C). The χ profile of the ZnTiN₂-300C-sapph films nearly approaches that of the single crystal sapphire substrate on our diffractometer (±2° from the surface normal, χ_{FWHM}=1.4°).

A subset of ZnTiN₂-300C-sapph films were grown with a Sn-containing Zn target and contain approximately 12% Sn/(Sn+Zn+Ti) by XRF. These Sn-containing films (hereafter referred to as “Sn: ZnTiN₂-300C-sapph”) exhibit comparable crystalline quality by XRD to those grown without Sn, but show an average shift of the (002) peak to 1° lower 2θ values. This shift is consistent with an expansion of the crystal lattice expected from Sn incorporation into the ZnTiN₂ structure. While the difference in crystalline quality appears negligible by XRD, the Sn: ZnTiN₂ films exhibit notable differences from the films that do not contain Sn, which will be described herein.

### Microstructural Investigations by Electron Microscopy

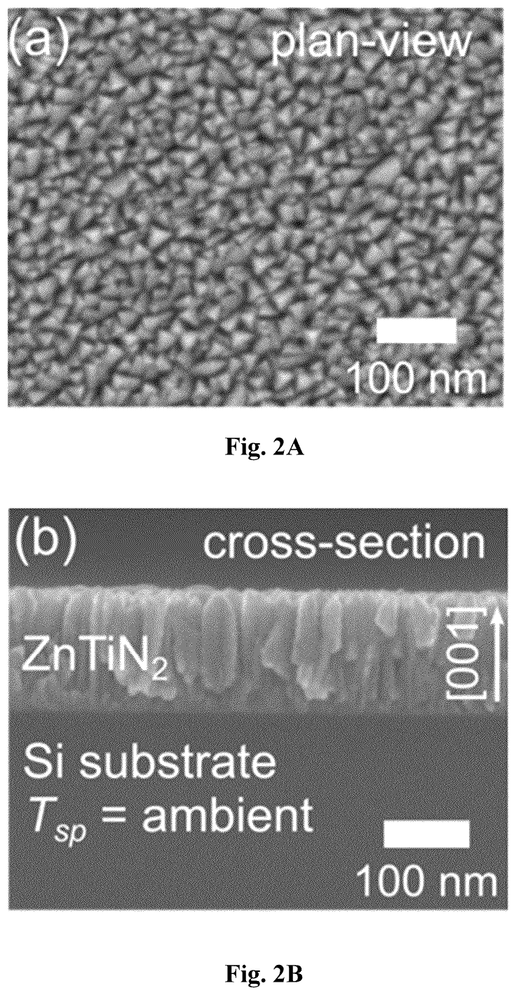

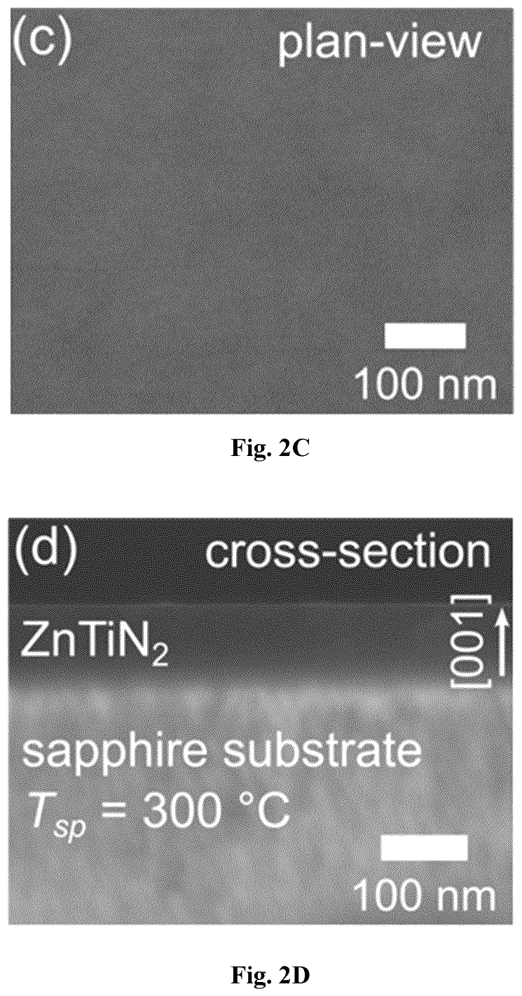

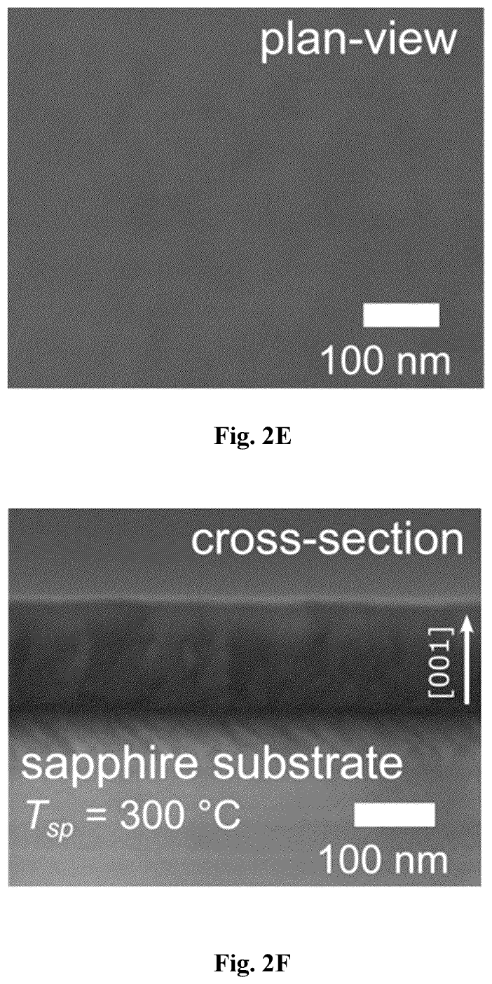

Improvements in ZnTiN₂ film crystalline quality with templating and high-temperature growth were also tracked by scanning electron microscopy (SEM) imaging. The ZnTiN₂-AT-Si film exhibits a nanocrystalline, columnar-grained microstructure with a triangular faceted surface morphology as seen from both plan-view and cross-sectional SEM (FIGS. 2A-2B). This textured film morphology is seen quite commonly in sputtered nitride thin films. In contrast, the ZnTiN₂-300C-sapph film exhibits a very homogeneous microstructure in both plan-view and cross-sectional SEM (FIGS. 2C-2D). The lack of distinct microstructural features is consistent with a marked improvement in crystalline quality. The Sn: ZnTiN₂-300C-sapph films also exhibit the same high-quality homogenous microstructure by SEM (FIGS. 2E-2F).

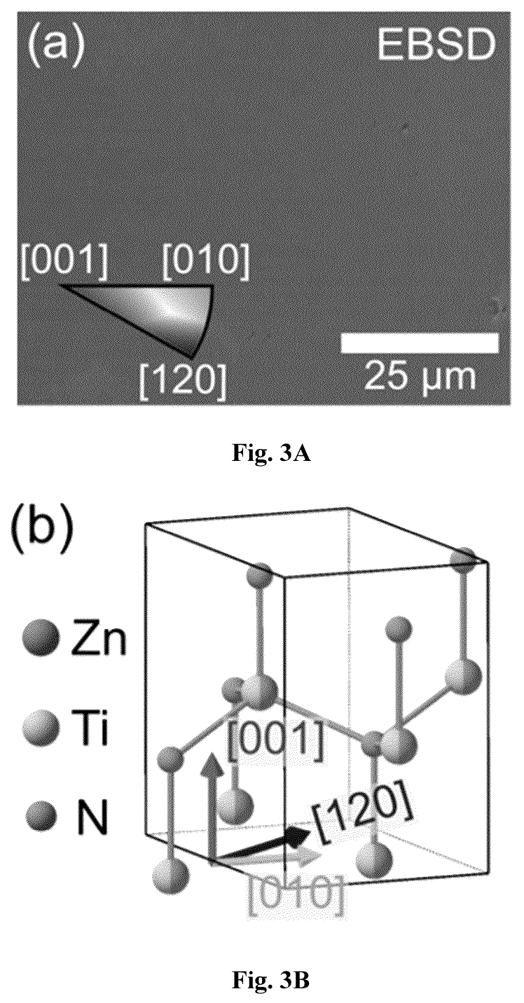

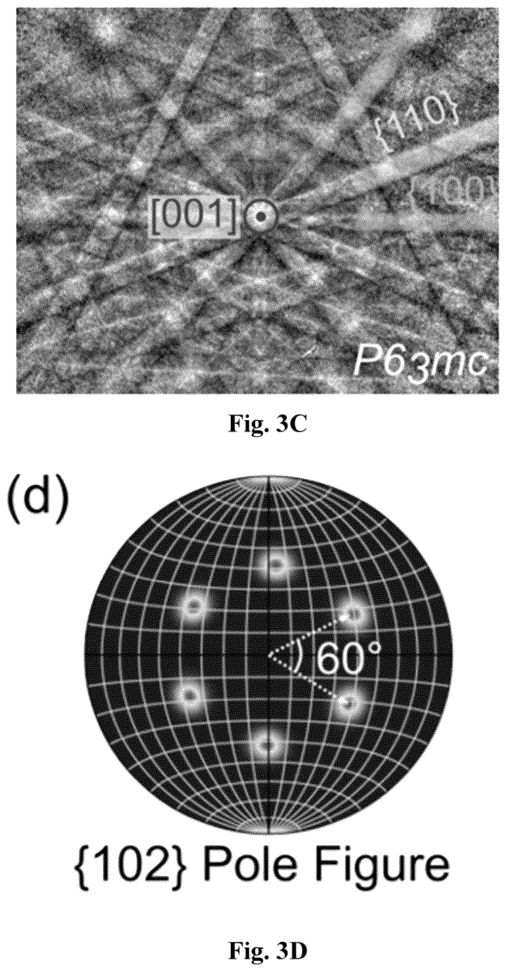

While the improvement in crystal quality observed in SEM is remarkable, it cannot be quantified. Electron backscatter diffraction (EBSD) was used to further investigate the improvement in crystalline orientation with improved growth conditions, especially the in-plane orientation of ZnTiN₂ that was not probed by XRD. Automated EBSD orientation maps could not be acquired on the ZnTiN₂-300C-sapph films due to surface roughness (R_{RMS}≈3.00 nm) which was sufficiently high to obscure the electron backscatter diffraction patterns (EBSPs) and prevent software indexing. However, manually investigating the crystalline orientation by probing many locations across the film (>5000 μm² area) showed an identically oriented electron backscatter diffraction pattern (EBSP) at every inspected point (a representative EBSP is shown in FIG. 3C). Even though automated orientation maps could not be produced, this manual EBSD investigation along with the XRD and SEM indicates that the ZnTiN₂ films grown on sapphire at elevated temperature are very uniformly oriented in all three crystallographic directions across the large areas that were examined.

Surprisingly, despite the similarities in XRD and SEM between films grown with and without Sn, the Sn: ZnTiN₂-300C-sapph films exhibited very low surface roughness (R_{RMS}≈0.55 nm), affording clear EBSPs that can be automatically indexed to generate EBSD orientation maps. An inverse pole figure (IPF) map for the Z-axis (normal to the film surface) from a 78 μm×63 μm region of a Sn: ZnTiN₂-300C-sapph film (FIG. 3A) shows a completely homogeneous film oriented with the direction parallel to the film growth direction. Corresponding X- and Y-axis IPF maps confirm the homogeneous crystal orientation in-plane with respect to the film/substrate interface. A crystal model of ZnTiN₂ in FIG. 3B indicates the crystal directions corresponding to the EBSD map axes. Multiple regions of similar size were measured on this film and showed the same uniform orientation. The average angular misorientation of each pixel with respect to its neighboring pixels (kernel averaged misorientation, KAM) is 0.35°±0.09°, confirming a very highly oriented film. The KAM of a commercial epi-ready GaN on sapphire template (3L Corporation®) measured on this instrument is 0.18°±0.07°. The smoother surfaces of the Sn: ZnTiN₂ films compared to the films grown without Sn are possibly explained by Sn acting as a surfactant, which has been observed in other nitride systems when supplying group IV elements (Si) during growth. Surfactants can promote 2-dimensional layer-by-layer growth, which has been shown to improve not only the surface quality, but also other material properties, of nitride thin films.

A representative electron backscatter diffraction pattern (EBSP) (FIG. 3C) from the Sn: ZnTiN₂-300C-sapph film shows strong Kikuchi band intensities and is indexed to the wurtzite P6₃mc space group, as expected from the cation-disordered ZnTiN₂ crystal structure. The same orientation indexed to P6₃mc was also observed in the EBSPs manually acquired from ZnTiN₂ films grown without Sn. A {102} pole figure (FIG. 3D) further confirms the Sn: ZnTiN₂-300C-sapph film is highly oriented in the planes off-axis from the growth direction; the pole figure exhibits six distinct peaks, separated by 60°, which clearly shows the six-fold rotational symmetry of the hexagonal wurtzite crystal structure. The combination of both in-plane and out-of-plane orientation (with respect to the growth direction) observed with EBSD across large areas confirms the single-crystal-like nature of these ZnTiN₂ films grown with and without Sn on sapphire at elevated temperature.

### Electronic Transport Properties

Electrical resistivity and Hall effect measurements were used to evaluate differences in the electronic transport properties of ZnTiN₂ films grown on EXG glass and sapphire substrates, with and without Sn incorporation, at ambient and elevated growth temperatures (Table 1). The electrical resistivity for the films grown at Tₛₚ=ambient were nearly identical; carrier concentrations and mobilities of films grown at Tₛₚ=ambient could not be measured due to having Hall voltages below the measurement limit (<100 nV) of the Hall system. The ZnTiN₂-300C-sapph film had a significantly lower resistivity compared to the ZnTiN₂ films grown at ambient temperature, likely due to a combination of increased material quality and large n-type carrier concentration. The Sn: ZnTiN₂-300C-sapph exhibited a resistivity slightly higher than the ZnTiN₂-300C-sapph film but notably lower than the ZnTiN₂ films grown at ambient temperature. This agrees with the observed improvements in material quality and its lower n-type carrier concentration compared to the ZnTiN₂-300C-sapph film. Assuming a maximum mobility of 0.001 cm²V⁻¹s⁻¹, corresponding to the minimum measurement limit of the Hall system, we estimate a minimum carrier concentration of n≈10²¹ cm⁻³ for the films grown at ambient temperature. Therefore, due to similar carrier concentrations across all ZnTiN₂ films, the observed decrease in electrical resistivity of the films grown at elevated temperature can be at least partially attributed to their enhanced crystalline quality, most likely due to the elimination of grain boundary scattering because of their single-crystalline structure.

TABLE 1
Electrical resistivity and Hall effect measurements of
ZnTiN₂ films deposited under different growth conditions.

| | | | Carrier |
|---|---|---|---|
| | Resistivity | Mobility | concentration |
| Sample | (Ω-cm) | (cm²V⁻¹s⁻¹) | (cm⁻³) |
| ZnTiN₂-AT-EXG | 3.89 ± | <0.001 | ≈10²¹ |
| | 0.11 | | |
| ZnTiN₂-AT-sapph | 3.97 ± | <0.001 | ≈10²¹ |
| | 0.10 | | |
| ZnTiN₂-300C-sapph | 0.123 ± | (1.68 ± | (3.01 ± |
| | 0.004 | 0.036) × 10⁻² | 0.09) × 10²¹ |
| Sn:ZnTiN₂- | 0.735 ± | (4.58 ± | (1.85 ± |
| 300C-sapph | 0.006 | 0.22) × 10⁻² | 0.01) × 10²⁰ |

Carrier mobilities of 0.0168±0.0004 cm²V⁻¹s⁻¹ and 0.0458±0.0022 cm²V⁻¹s⁻¹ were measured for the ZnTiN₂-300C-sapph and Sn: ZnTiN₂-300C-sapph films, respectively. While these are not exceptional carrier mobilities relative to highly-developed nitride semiconductors (40-80 cm²V⁻¹s⁻¹ for GaN with n≈10²⁰ cm⁻³), they are comparable to, or even better than, oxide PEC electrode materials (0.044 cm²V⁻¹s⁻¹ for undoped BiVO₄ and 0.008 cm²V⁻¹s⁻¹ for CuV₂O₆ with n≈10¹⁸ cm⁻³) and indicates the success of our approach in improving the optoelectronic quality of the ZnTiN₂ semiconductor. Additional efforts to reduce the carrier concentration in these films would likely further improve the carrier mobility.

### Optical Properties and Photoexcited Carrier Kinetics

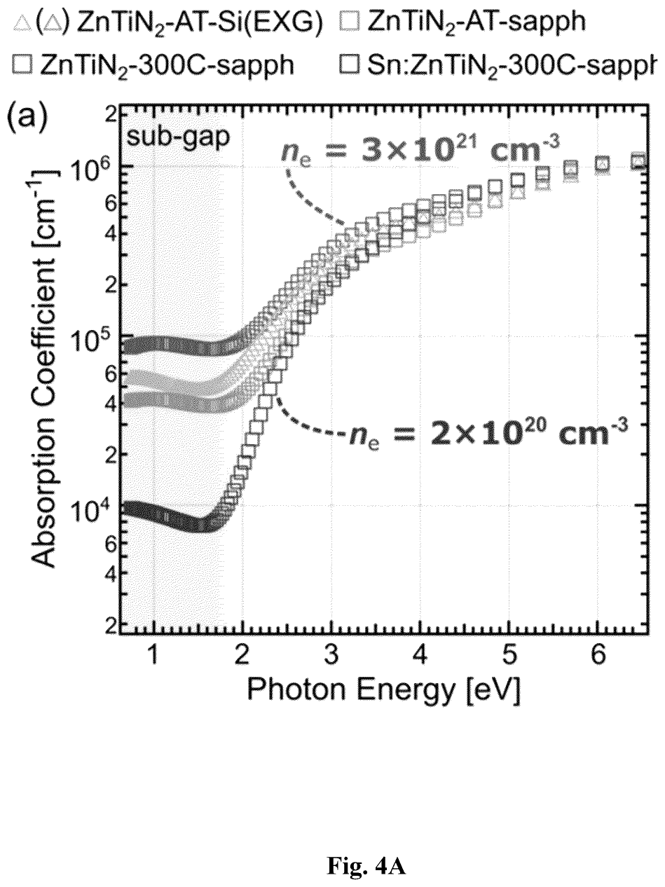

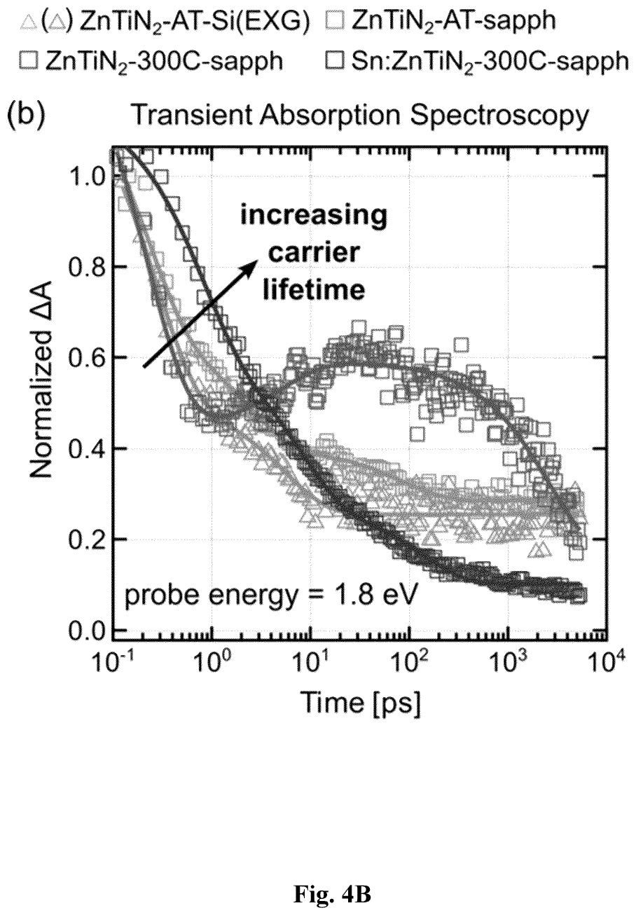

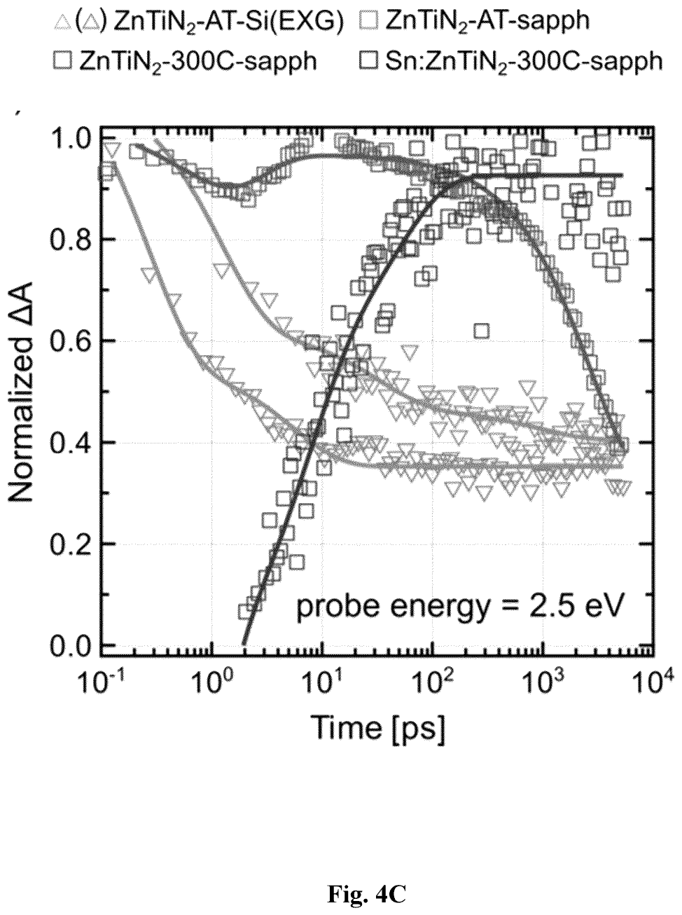

Spectroscopic ellipsometry was used to track changes in the optical properties of the ZnTiN₂ films as a function of growth conditions. Plots of absorption coefficient versus photon energy were extracted from the modeled ellipsometry data (FIG. 4A). Baseline ZnTiN₂-AT-Si films show an absorption onset near 2 eV, as expected from prior work. In these films, there is a relatively large amount of absorption present at photon energies in the “sub-gap” region, below 2 eV, compared to typical high-quality semiconductor materials that exhibit steep absorption onsets at their bandgap energy. High optical absorption in the sub-gap region is generally assumed to be associated with defect energy states that can arise from a variety of crystallographic defects or chemical impurities. Grain boundaries in polycrystalline films, as well as oxygen contamination that was observed in our prior work,¹¹ are likely culprits for high sub-gap optical absorption observed in the ZnTiN₂ films grown on Si at ambient temperature. The ZnTiN₂-AT-sapph film, which showed slightly better crystallinity by XRD (FIG. 1B), also show a slight improvement (that is, a decrease) in sub-gap absorption, although the difference is small.

Increasing the growth temperature on sapphire substrates to Tₛₚ of 300° C. resulted in an unexpected increase in sub-gap absorption in the ZnTiN₂-300C-sapph film. In contrast, the Sn: ZnTiN₂-300C-sapph film exhibits a dramatic decrease in sub-gap absorption, despite growth under nominally identical conditions. As shown from the Hall results, the ZnTiN₂-300C-sapph film has an order of magnitude higher carrier density compared to its Sn: ZnTiN₂ counterpart, which corroborates and could explain the large difference in free carrier absorption. However, the significant decrease in sub-gap absorption observed in the Sn: ZnTiN₂-300C-sapph film compared to the other films analyzed is very likely due to a combined effect of having a lower carrier density and the single-crystal nature of these films (i.e., elimination of grain boundaries). For the highest optical quality Sn: ZnTiN₂ films, a band gap of ˜1.8-2 eV is calculated from where the absorption coefficient curve crosses 104 cm⁻¹.

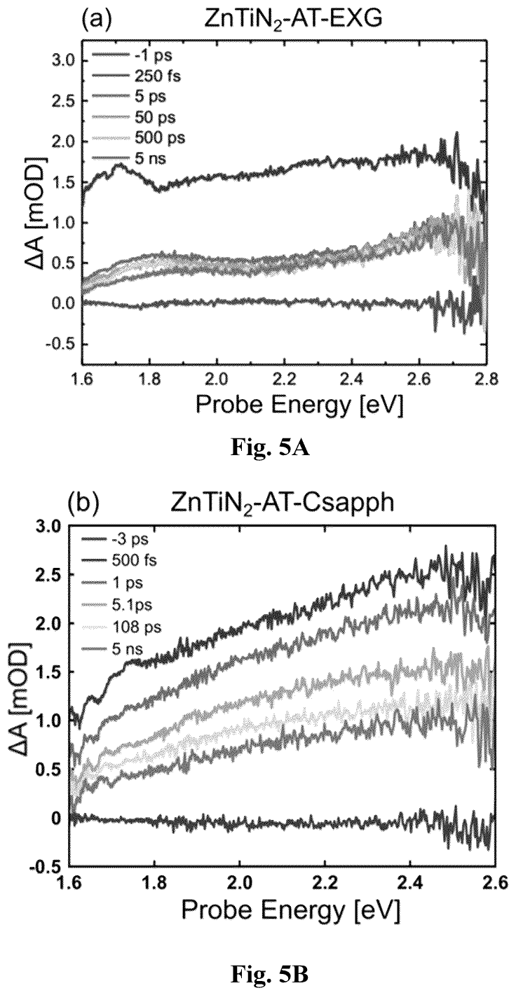

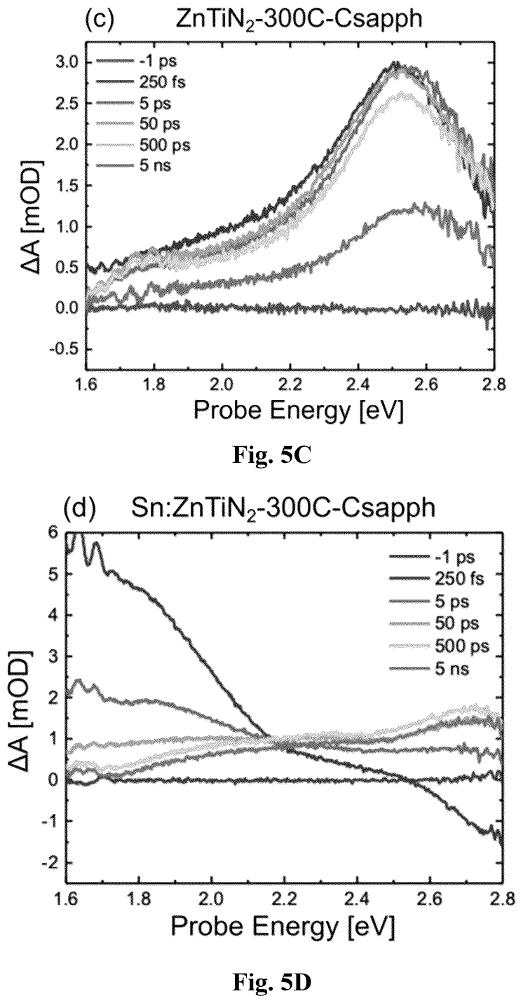

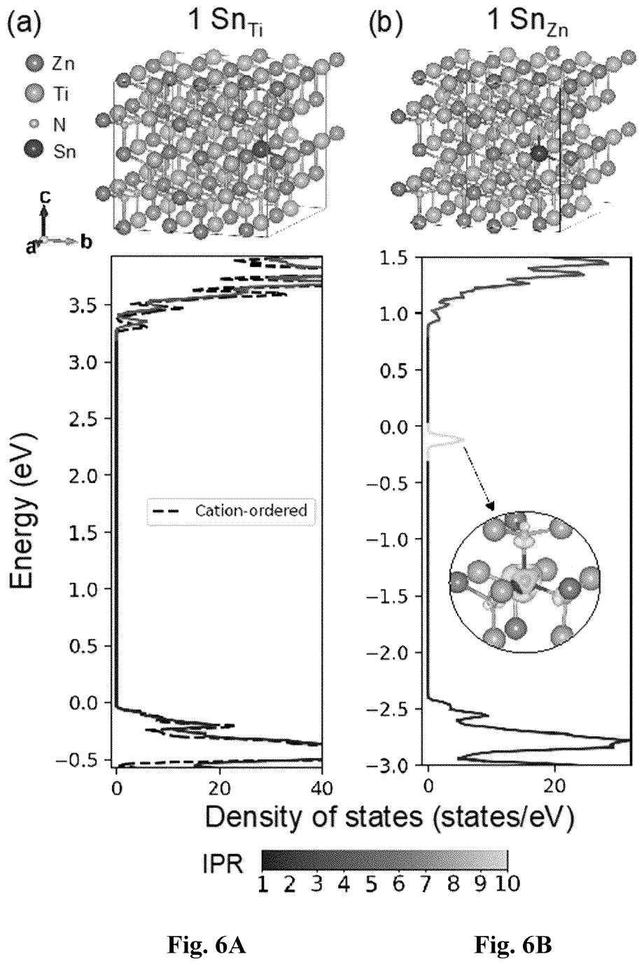

Transient absorption (TA) spectroscopy was used to assess the photoexcited carrier dynamics of the ZnTiN₂ thin films produced in this study. Only ZnTiN₂ films grown on EXG glass and sapphire substrates were probed using TA, as transmission-mode measurements are not possible on opaque Si substrates. Films grown at ambient temperature on EXG (ZnTiN₂-AT-EXG) and Si (ZnTiN₂-AT-Si) appear identical based on all methods used to characterize them. Full TA spectra are shown in FIGS. 5A-5D. The spectra of all films exhibit similar characteristics after photoexcitation at 3.1 eV, including a broad photoinduced absorption spanning the visible regime with a distinct peak centered around 2.6 eV. Differences arise when monitoring the evolution of these features over time.

We monitored the kinetics of the films at two distinct wavelengths at the low (1.8 eV) and high (2.5 eV) energy edges of the spectra. The dynamics at 1.8 eV (FIG. 4B) show a rapid evolution within the first 1 ps following photoexcitation in all films. A qualitative comparison of decay rates within this region shows a similar trend to the optical sub-gap absorption trends, where lower optical quality is associated with faster decay kinetics. Rigorous TA analysis in the BiVO₄ photoelectrode system has attributed these shorter ps timescale processes to excited carrier thermalization and defect-mediated fast electron-hole recombination.³⁷ Loosely attributing these assignments to the ZnTiN₂ system suggests that higher optical quality films exhibit longer photoexcited carriers lifetimes and less carrier recombination due to defect states, which are both important metrics to optimize for attaining high PEC device performance. From 1 ps onward, all films except for the ZnTiN₂-300C-sapph film continue to exhibit kinetic decay signatures typical of photoexcited carrier thermalization and recombination in semiconductor materials. The ZnTiN₂-300C-sapph film, however, shows a growth signature before starting to decay again around 30 ps. We attribute this unique growth feature to an increased population of excited carrier trapping in the ZnTiN₂-300C-sapph film due to its significantly large carrier concentration as measured by Hall effect.

To further study the differences in carrier dynamics between synthesis conditions, transient absorption kinetics were fit at a probe energy of 2.5 eV (FIG. 4C) which is more sensitive to the kinetics of trapped charge carriers. Both films grown at ambient temperature display similar kinetic decay signatures at 2.5 eV and 1.8 eV probe energies, further indicating that excited carrier lifetime is dominated by fast electron-hole recombination in these films. In contrast, the films grown at elevated temperature show positive growth signatures from the 2.5 eV probe energy starting around 2 ps that persist until around 1 ns. These kinetic signatures suggest a significantly larger degree of charge carrier trapping prior to recombination compared to films grown at ambient temperature. A possible explanation is the absence of grain boundaries, which typically act as recombination sites, in the elevated temperature films (which are single-crystalline) that allows trapping to become dominant at longer time scales. The ZnTiN₂-300C-sapph film 2.5 eV kinetic data reaches a maximum after a few ps, followed by a significant decay after 1 ns. The similar trends observed in the 1.8 eV and 2.5 eV kinetic data for the ZnTiN₂-300C-sapph film suggest an abundance of carrier trap states across the probed energy range, consistent with its high carrier concentration. In contrast, the Sn: ZnTiN₂-300C-sapph film grows to a maximum at around 100 ps and shows only a minor decay signature after a few ns. The later onset of carrier trapping and more gradual kinetic decay observed in the Sn: ZnTiN₂-300C-sapph film, combined with its more typical exponential decay signature at 1.8 eV, suggests a different mechanism where carriers transition from their initial excited states to longer lived trap states before eventually recombining on the ns time scale. A more in-depth spectroscopic investigation would be required to quantitatively correlate TA kinetics to carrier concentration in ZnTiN₂. However, the overall longer photoexcited carrier lifetimes observed for the Sn: ZnTiN₂-300C-sapph film at both probe energies provide further evidence of its enhanced optoelectronic properties compared to the ZnTiN₂ films without Sn.

### Influence of Sn Incorporation on Electronic Band Structure

To gain additional understanding of the influence of Sn on the optoelectronic properties of ZnTiN₂, we perform first-principles calculations based on density functional theory (DFT). Small concentrations of Sn are introduced into cation-ordered ZnTiN₂, with Sn substituting for either Zn or Ti. We expect Sn to take up its more stable oxidation state of 4+, and so replacing Zn with Sn is expected to effectively introduce two electrons, whereas Sn replacing Ti is charge neutral. Our computed site-projected density of states (DOS) for a single Sn substitution (1.6% of cation sites) on Ti or Zn sites in 128-atom cation-ordered ZnTiN₂ supercells (FIGS. 9A-9B) indicates the DOS is mostly unchanged when Sn substitutes for Ti, while a deep gap state appears when Sn is substituted for Zn. This deep gap state contrasts with the optical absorption measurements that show the Sn: ZnTiN₂-300C-sapph film exhibiting the lowest sub-gap optical absorption of all films studied, suggesting that Sn likely substitutes for Ti rather than Zn.

However, DFT calculations of Sn substitution accounting for the cation-disordered structure of the ZnTiN₂ films synthesized in this work are called for, as the cation disorder reduces the conduction band edge energies and increases valence band edge energies (leading to an overall reduction in band gap). Thus, we perform DFT calculations where we substitute Sn for Zn in a supercell that includes cation disorder and recompute the DOS and inverse participation ratio. In a cation-disordered supercell, each Zn and Ti has a different local atomic environment, a consequence of the disorder. We use DFT to compute the energetics of Sn substitution on Zn sites with different local environments and find the formation energy of the Sn_{Zn} substitutional defect decreases for Zn sites with more Zn neighboring cations (i.e., it is easier to replace Zn with Sn in Zn clusters). For example, the Sn_{Zn} formation energy for a Zn site with 8 Zn and 4 Ti neighbors is 55.1 meV per formula unit (f.u.) lower than that for a Zn site with 3 Zn and 9 Ti neighbors. This is consistent with previous findings that Zn-rich regions or clusters are relatively energetically unfavorable. These calculations suggest that Sn incorporation, as well as enhanced growth kinetics at elevated growth temperatures, suppresses Zn clustering in the films, reducing the likelihood of fully Zn coordinated N motifs, which have been shown to introduce localized gap states, and promotes improved carrier transport and optical properties. In contrast, replacing Ti with Sn shows little variation, about 1.6 meV per f.u. for the sites we studied.

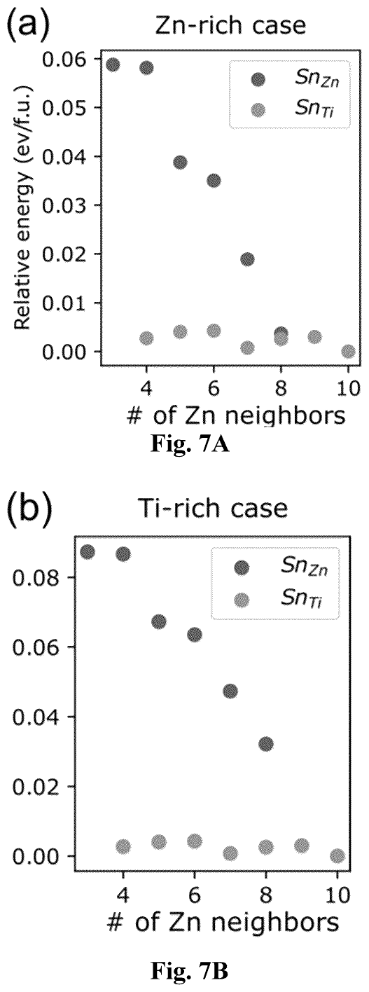

We compare the formation energies of Sn_{Zn} and Sn_{Ti} (FIGS. 7A-7B), the relative difference between which originates from different total energies of one Zn- and Ti-replaced supercells and the chemical potentials of Zn and Ti, which depend on the synthesis conditions. Here we use the Zn-Ti-N phase diagram generated from Materials Project^{39,40} and DFT-PBE calculated energy of bulk metallic Zn and Ti, focusing on two extreme cases within the ZnTiN₂ phase space where (1) the Zn chemical potential is at its lowest and Ti chemical potential is at its highest, and (2) the Ti chemical potential is at its highest and Zn is at its lowest. In the first case, except for the most energetically desirable Sn_{Zn} defect where Sn replaces Zn with the most Zn neighbors, the formation energies of Sn_{Zn} range from 14.6 to 58.8 meV per f.u. larger than Sn_{Ti} formation energies. In the second case, all Sn_{Zn} have at least 27.8 meV per f.u. larger formation energies than those of Sn_{Ti}. Therefore, Sn is most likely to replace Ti sites and Zn sites within Zn clusters.

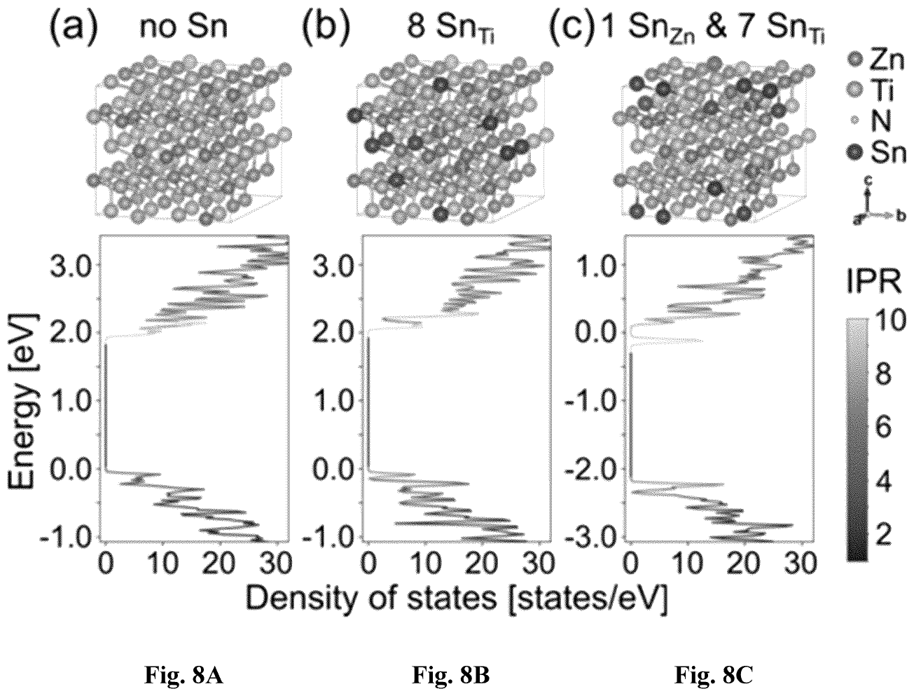

Cation disorder introduces a local charge imbalance that broadens both valence and conduction bands. As the conduction band broadens, the gap state can merge into the conduction band and manifest as a shallow defect state. FIGS. 8A-8C shows density of states and inverse participation ratios (IPF), which quantifies the degree of localization of the wavefunction on each site at each energy, computed with DFT from three cation disordered supercells: one with no Sn substitution (FIG. 8A), one with all eight Sn substitutions on Ti sites (12.5% of cation sites) (FIG. 8B) and one with Sn replacing one Zn site with the most Zn neighbors and seven randomly selected Ti sites (FIG. 8C). The density of states of the two supercells with Sn are similar to that of the supercell without Sn. The highest occupied state of the supercell shown in FIG. 8C has mainly Ti d character, suggesting that Sn_{Zn} is a shallow defect. Thus, our calculations demonstrate that energetically favorable Sn_{Zn} and Sn_{Ti} substitutional defects do not lead to mid-gap states in cation-disordered ZnTiN₂, and we further hypothesize that Sn dopants help ameliorate severe local charge imbalance associated with Zn clustering and result principally in shallow defect levels.

### CONCLUSIONS

In this example, we demonstrate heteroepitaxial growth of wurtzite-structured (cation-disordered) ZnTiN₂, a promising photoelectrode material for PEC CO₂R applications, on c-plane (001) sapphire substrates. By using lattice-matched substrates and depositing films at elevated temperature (300° C.), single-crystalline films of ZnTiN₂ are produced. Supplying Sn during growth on sapphire at elevated temperature reduces the surface roughness of the resulting Sn:ZnTiN₂ film considerably. This suggests that Sn acts as a surfactant, possibly by promoting 2-dimensional layer-by-layer growth. Additionally, the Sn:ZnTiN₂ films exhibited an order of magnitude lower n-type carrier concentration, implying a mechanism by which Sn decreases or compensates n-type dopants in the growing film, resulting in enhanced optical absorption properties, carrier mobilities, and photoexcited carrier lifetimes compared to films grown under the same conditions without Sn. DFT calculations suggest that Sn substitution on energetically-favorable Zn and Ti cation sites in cation-disordered ZnTiN₂ does not appreciably influence the optoelectronic properties and may even mitigate local charge imbalance in regions otherwise negatively impacted by Zn clustering. All these observations indicate an enhancement of charge carrier transport due to improvements in crystalline material quality, most notably the elimination of n-type point defects and grain boundaries in the single-crystal Sn: ZnTiN₂ material.

Overall, the optimization of ZnTiN₂ thin film crystalline quality and associated improvements to optoelectronic properties are critical steps towards ZnTiN₂ photoelectrodes with efficient photon absorption and photoexcited carrier extraction. An additional benefit of high-quality heteroepitaxial growth is the smoother film surface that enables more simplified development and characterization of electrochemically stable surface oxide layers. Studying and manipulating the interface between the ZnTiN₂ film and these oxide layers, as well as the opposite interface with the substrate (and back contact layer in a device configuration), will be crucial for ensuring optimal electronic transport across the PEC device as a whole. In summary, a combination of these current and future efforts will be necessary for further optimizing the ZnTiN₂ thin films for PEC applications.

### Experimental Methods

### Synthesis

Thin films of Zn-Ti-N were deposited by radiofrequency co-sputtering in a custom vacuum chamber containing a cryoshroud surrounding the plasma zone. All films were deposited for 2 hours onto stationary substrates to create a lateral compositional gradient across the sample or onto rotating substrates once deposition conditions were well-defined. A combination of Zn, Ti, and alloy ZnTi targets (all 2″ diameter) were used to allow for compositional flexibility throughout the film optimization process due to the dissimilar temperature-dependent sputtering rates of Zn and Ti. A Zn target containing approximately 5 atom % Sn, measured by XRF, was used for depositing the Sn-containing ZnTiN₂ films. RF power densities on each target were tuned at each set of growth conditions such that samples containing nominally stoichiometric films with one-to-one Zn: Ti ratios were produced. Specific growth conditions and target powers are reported in Table 2. Substrates used in this work were either single-side-polished (001)-oriented silicon with native oxide, Corning EXG glass, or double-side-polished (001)-oriented Al₂O₃ (sapphire). For all depositions, a chamber base pressure <4×10⁻⁷ Torr was reached prior to flowing 20 sccm of Ar and 10 sccm of N₂ while maintaining a chamber pressure of 3.5×10⁻³ Torr by controlling a partially closed gate valve to the turbomolecular pump. The deposition temperature was either left at ambient or increased using a UV lamp to heat the Inconel platen from the backside, thereby heating the substrate which is in direct thermal contact with the front of the platen. Growth temperatures were chosen and reported based on the heater setpoint (Tₛₚ), which was calibrated using a thermocouple to measure the temperature at the center of the front-side of the platen where the substrate is held and does not account for unintentional heating from the RF sputtering process. The actual temperature at the substrate/growth surface was not measured.

TABLE 2
Deposition parameters for ZnTiN₂ films.

| Sample ID | Substrate | Tₛₚ [° C.] | Base Pressure [Torr] | Zn Power [W] | Zn (5% Sn) Power [W] | Ti Power [W] | ZnTi Power [W] | $\frac{Sn}{( Sn + Zn + Ti )}$ |
|---|---|---|---|---|---|---|---|---|
| ZnTiN₂-AT- | silicon | ambient | 2.9 × 10⁻⁷ | — | — | 100 | 150 | — |
| Si | | (~25) | | | | | | |
| ZnTiN₂-AT- | EXG glass | ambient | 0.9 × 10⁻⁷ | — | — | 100 | 150 | — |
| EXG | | (~25) | | | | | | |
| ZnTiN₂-AT- | sapphire | ambient | 2.5 × 10⁻⁷ | — | — | 100 | 150 | — |
| sapph | | (~25) | | | | | | |
| ZnTiN₂-300 | sapphire | 300 | 1.8 × 10⁻⁷ | 50 | — | — | 150 | — |
| C-sapph | | | | | | | | |
| Sn:ZnTiN₂- | sapphire | 300 | 2.0 × 10⁻⁷ | — | 40 | — | 150 | ~12% |
| 300C-sapph | | | | | | | | |

.

### Characterization

Cation composition was analyzed with a Fischer XDV-SDD X-ray fluorescence spectrometer to measure the lateral compositional gradients across the sample using an automated mapping routine and to locate sample positions containing the desired stoichiometric ZnTiN₂ composition. Quantification routines for cation composition in XRF were calibrated using compositional data acquired from Rutherford backscattering spectrometry.

A Bruker D8 Discover equipped with an area detector was used to collect 2-dimensional X-ray diffraction plots at each sample position using an automated mapping routine. 2D XRD spectra were acquired over a range of 2θ=19-52° and χ=60-120° using Cu-Kα radiation. Integrated 1-dimensional XRD plots were calculated by integrating over the entire χ range to get intensity versus 2θ and by integrating over just the 2θ range containing the ZnTiN₂ (002) diffraction peak (ca.) 34-37° to get intensity versus χ.

Scanning electron microscopy was performed using either a Hitachi S-4800 or FEI Nova NanoSEM 630 operating at 3 kV accelerating voltage and a working distance of 3-5 mm. Electron backscatter diffraction was conducted using an Oxford Symmetry detector and Aztec software on the FEI Nova NanoSEM 630 operating at a 20 kV accelerating voltage and 12 nA beam current. A resolution of 1024×896 pixels with 83.4 nm pixel size was used for mapping. The mean angular deviation between the measured diffraction patterns and simulated reference wurtzite crystal structure was 0.68°±0.09°. All films studied in this work were thicker than 100 nm, which is greater than the typically cited upper limit on information depth in EBSD (around 50 nm), ensuring that EBSD data were acquired only from the film and not the underlying substrate.

Spectroscopic ellipsometry data were acquired using a J.A. Woollam Co. M-2000 variable angle ellipsometer at incident angles of 65°, 70°, and 75° over a photon energy range of 0.73-6.46 eV. Raw Ψ and Δ data were modeled and fit using the CompleteEASE software (version 6.63) to extract optical parameters n, k, and absorption coefficient. A generalized oscillator model was constructed using a PSemi-M0 oscillator to fit the ZnTiN₂ optical absorption edge and a single Drude oscillator to fit the sub-gap free carrier absorption region below 2 eV.

Resistivity and Hall effect measurements were done at ambient temperature on a LakeShore FastHall system in a van der Pauw geometry using indium contacts soldered onto the corners of 10 mm×10 mm square pieces cleaved from the larger sample.

Transient absorption spectroscopy data were collected using a Coherent Libra Ti: sapphire laser (1 kHz, 800 nm (1.55 eV) fundamental, 150 fs pulse width). The 3.1 eV (400 nm, 500-1200 nJ/pulse) pump pulse was generated in a TOPAS-C optical parametric amplifier and the white light probe pulses were produced via supercontinuum generation in a thin sapphire window (λ_{probe}=2.8-1.55 eV). A mechanical delay stage was used to delay the probe relative to the pump and pump and probe were spatially overlapped at the sample. A portion of the probe was picked off before the sample to reduce noise to <0.1 mOD. A fiber-optic coupled multichannel spectrometer with a CMOS sensor was used to monitor changes in the probe. Helios software from Ultrafast Systems was used to collect the data and the data were chirp corrected and analyzed with either Ultrafast Systems' SurfaceXplorer software or custom chirp correction code in Igor PRO and fit using the Imfit Python package.

DFT calculations were performed with the Vienna Ab Initio Simulation Package (VASP) and projector augmented wave (PAW) potentials, treating 3d² 4s², 3d¹⁰ 4s², and 2s² 2p³ electrons explicitly for Ti, Zn, and N, respectively. We used the exchange-correlation functional of Perdew, Burke, and Ernzerhof (PBE) 41 to compute total energies, Hellmann-Feynman forces, and optimize the atomic structure. The internal coordinates were relaxed while lattice parameters were fixed. An energy cutoff of 600 eV was used and total energies were converged to within 10-7 eV/atom and all Hellmann-Feynman forces are below 0.01 eV/Å on each atom. For our electronic structure calculations, we used a Heyd-Scuseria-Ernzerhof (HSE06) screened hybrid functional. Our supercells contained 128 atoms (32 f.u.). For PBE calculations, a I-centered 4×4×4 k-mesh was used; for hybrid calculations, a Γ-centered 2×2×2 k-mesh was used. Gaussian smearing was used in our Brillouin zone integrations, with a smearing parameter of 0.02 eV in all calculations. These computations are performed without considering the presence of oxygen.

The present invention may be further understood by the following non-limiting examples:

Example 1. A device comprising:
a first cation selected from group II, a second cation selected from group IV or group V and a nitride anion;
an additive selected from group III, group IV or group V;
wherein the additive replaces a portion of the first cation, the second cation or both via isovalent substitution thereby improving surface morphology, optoelectronic properties, or both; and
wherein the device is an optoelectronic semiconductor.

Example 2. The device of example 1, wherein the additive is selected from Sn, Sb or Bi.

Example 3. The device of example 1 or 2, wherein the additive replaces a portion of the second cation.

Example 4. The device of any of examples 1-3, wherein the device is grown on a sapphire substrate.

Example 5. The device of example 4, wherein the sapphire substrate has a c-plane (001) orientation.

Example 6. The device of any of examples 1-5, wherein the device is grown at an elevated temperature greater than or equal to 100° C.

Example 7. The device of example 6, wherein the temperature is about 300° C.

Example 8. The device of any of examples 1-7, wherein the device has a reduced resistivity in comparison to a device without the additive, the sapphire substrate, the elevated temperature or a combination thereof.

Example 9. The device of any of examples 1-8, wherein the device has a resistivity less than or equal to 1.0 Ω-cm.

Example 10. The device of any of examples 1-9, wherein the device has a reduced bandgap in comparison to a device without the additive, the sapphire substrate, the elevated temperature or a combination thereof.

Example 11. The device of any of examples 1-10, wherein the device has a bandgap selected from the range of 1.5 to 2.5 eV.

Example 12. The device of any of examples 1-11, wherein the device has an increased carrier mobility in comparison to a device without the additive, the sapphire substrate, the elevated temperature or a combination thereof.

Example 13. The device of any of examples 1-12, wherein the device has a carrier mobility greater than or equal to 0.02 cm²V⁻¹s⁻¹.

Example 14. The device of any of examples 1-13, wherein the first cation is selected from Zn and Mg.

Example 15. The device of any of examples 1-14, wherein the second cation is selected from Ti, Ge and Nb.

Example 16. The device of any of examples 1-15, wherein the first cation comprises Zn and the second cation comprises Ti.

Example 17. A method comprising:
growing a semiconductor comprising a first cation selected from group II, a second cation selected from group IV or group V and a nitride anion on a sapphire substrate at a temperature greater than or equal to 100° C.;
substituting the first cation, the second cation or both with an additive selected from group III, group IV or group V.

Example 18. The method of example 17, wherein the additive is selected from Sn, Sb or Bi.

Example 19. The method of example 17 or 18, wherein the sapphire substrate has a c-plane (001) orientation.

Example 20. The method of any of examples 17-19, wherein the temperature is about 300° C.

Example 21. The method of any of examples 17-20, wherein the first cation is selected from Zn and Mg.

Example 22. The method of any of examples 17-21, wherein the second cation is selected from Ti, Ge and Nb.

Example 23. The method of any of examples 17-22, wherein the step of growing the semiconductor comprises physical vapor deposition.

Example 24. The method of any of examples 17-23, wherein the step of growing the semiconductor comprises sputtering

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

1. A device comprising:
a first cation selected from group II, a second cation selected from group IV or group V and a nitride anion;
an additive selected from group III, group IV or group V;
wherein the additive replaces a portion of the first cation, the second cation or both via isovalent substitution thereby improving surface morphology, optoelectronic properties, or both; and
wherein the device is an optoelectronic semiconductor.

2. The device of claim 1, wherein the additive is selected from Sn, Sb or Bi.

3. The device of claim 1, wherein the additive replaces a portion of the second cation.

4. The device of claim 1, wherein the device is grown on a sapphire substrate.

5. The device of claim 4, wherein the sapphire substrate has a c-plane (001) orientation.

6. The device of claim 1, wherein the device is grown at an elevated temperature greater than or equal to 100° C.

7. The device of claim 1, wherein the device has a reduced resistivity in comparison to a device without the additive, the sapphire substrate, the elevated temperature or a combination thereof.

8. The device of claim 1, wherein the device has a resistivity less than or equal to 1.0 Ω-cm.

9. The device of claim 1, wherein the device has a reduced bandgap in comparison to a device without the additive, the sapphire substrate, the elevated temperature or a combination thereof.

10. The device of claim 1, wherein the device has a bandgap selected from the range of 1.5 to 2.5 eV.

11. The device of claim 1, wherein the device has an increased carrier mobility in comparison to a device without the additive, the sapphire substrate, the elevated temperature or a combination thereof.

12. The device of claim 1, wherein the device has a carrier mobility greater than or equal to 0.02 cm²V⁻¹s⁻¹.

13. The device of claim 1, wherein the first cation is selected from Zn and Mg.

14. The device of claim 1, wherein the second cation is selected from Ti, Ge and Nb.

15. The device of claim 1, wherein the first cation comprises Zn and the second cation comprises Ti.

16. A method comprising:
growing a semiconductor comprising a first cation selected from group II, a second cation selected from group IV or group V and a nitride anion on a sapphire substrate at a temperature greater than or equal to 100° C.;
substituting the first cation, the second cation or both with an additive selected from group III, group IV or group V.

17. The method of claim 16, wherein the additive is selected from Sn, Sb or Bi.

18. The method of claim 16, wherein the sapphire substrate has a c-plane (001) orientation.

19. The method of claim 16, wherein the first cation is selected from Zn and Mg.

20. The method of claim 16, wherein the second cation is selected from Ti, Ge and Nb.
